(19) United States
(12) Patent Application Publication
(10) Pub. No.: US 2008/0197864 A1
(43) Pub. Date: Aug. 21, 2008

(54) RESISTANCE MEASURING METHOD

(75) Inventor: Yutaka Fukui, Kawasaki (JP)

Correspondence Address: GREER, BURNS & CRAIN, 300 S WACKER DR, 25TH FLOOR, CHICAGO, IL, 60606, US

(73) Assignee: FUJITSU LIMITED, Kawasaki-shi (JP)

(21) Appl. No.: 12/030,382

(22) Filed: Feb. 13, 2008

(30) Foreign Application Priority Data
Feb. 15, 2007 (JP) 2007-035009

(51) Int. Cl. G01R 27/08

(52) U.S. Cl. 324/715

(57) ABSTRACT

A resistance measuring method for testing a device under test electrically connected to a pair of pads, by use of a measuring apparatus having a resistance measuring function. A voltage arising in the device under test is measured to calculate a resistance of the device under test from the current and voltage. The resistance measuring method includes, forming an electric connection pattern serially connecting the plurality of sets of the devices under test, causing a pair of probes for voltage measurement of the measuring apparatus to come into contact with the pair of pads of the device under test, and causing a pair of probes for current application of the measuring apparatus to come into contact with a pair of pads electrically connected by the electric connection pattern to each of the pair of pads of the device under test.

### BACKGROUND

1. Field of the Invention

The present invention generally relates to a resistance measuring method for measuring a resistance of a device under test, and in particular, relates to a resistance measuring method using a plurality of probes. The present invention is suitable, for example, for a 4-wire resistance measuring method or a 6-wire resistance measuring method for measuring a resistance of a head mounted in a hard disc drive (HDD).

2. Description of the Related Art

With widespread proliferation of the Internet and the like in recent years, demands for providing large-capacity inexpensive HDDs are increasing. If the surface recording density is increased in response to larger density demands, the area on a recording medium of one bit, which is the minimum unit of magnetic recording information, is reduced. Therefore, miniaturization of a head for recording and playing back information with respect to such an area has been pursued.

The head has write elements and read elements, and a plurality of such elements are arranged on the same wafer during manufacture in units of bar to measure resistance. A 4-wire resistance measuring apparatus and a 6-wire resistance measuring apparatus are known for resistance measurement. Any 4-wire resistance measuring apparatus or 6-wire resistance measuring apparatus used for resistance measurement uses probes, and two such probes as a pair are brought into contact with a pair of pads connected to a device under test.

Other technologies include, for example, Japanese Patent Nos. 3276376 and 3420092.

In order to arrange more heads on a wafer, pads have been miniaturized along with the heads, for example, from the conventional ones measuring 100 μm per side to those measuring 50 μm or 70 μm. With the miniaturization of the pads, the diameter of a tip part of a probe to be pressed against a pad has been miniaturized from conventionally 50 μn to 20 μm or 30 μm. As probes become thinner, as described above, manufacturing the probes will become more difficult and also mechanical strength thereof will decline. About 20,000 elements are mounted on a wafer. If endurance of a 20 μm probe is 300,000 times, the probe will have to be replaced for every 15 wafers or so. Therefore, running costs of resistance measurement have been high due to greater frequency of replacement. Further, it is also difficult to arrange two probes on one pad in such a way that they do not mutually come into contact, requiring a high level of skill for work. High running costs and difficulty of manufacturing or arranging the probes has lead to an increase in cost of the head and eventually of HDD using the heads.

### SUMMARY

A resistance measuring method according to one aspect of the present disclosure includes, forming an electric connection pattern for testing that serially connects a plurality of sets of the devices under test, causing a pair of probes for voltage measurement of a measuring apparatus to come into contact with a pair of pads of the device under test, and causing a pair of probes for current application of the measuring apparatus to come into contact with a pair of pads electrically connected by an electric connection pattern to each of the pair of pads of the device under test.

Further, a resistance measuring method according to the another aspect of the present disclosure includes circularly forming an electric connection pattern for testing that serially connects three sets or more of the devices under test, causing a pair of probes for voltage measurement of a measuring apparatus to come into contact with a pair of pads of the three sets or more of the devices under test, causing a pair of probes for current application of the measuring apparatus to come into contact with a pair of pads electrically connected by an electric connection pattern to each of the pair of pads, and causing a pair of guard probes of the measuring apparatus to come into contact with a pair of pads among one pair or more of remaining pads mutually connected by the electric connection pattern for testing.

### BRIEF DESCRIPTION OF THE DRAWINGS

FIG. 1 is a block diagram of a measuring system to which a resistance measuring method of a first embodiment is applied;

FIG. 2 is an enlarged plane view of a wafer on which a plurality of bars are mounted and the bar thereof;

FIG. 3 is a schematic side view of the measuring system of the first embodiment;

FIG. 4 is a rear view of a printed board shown in FIG. 3;

FIG. 5 is a flow chart for illustrating the resistance measuring method of the first embodiment;

FIG. 6 is a plane view for illustrating a problem of a configuration of the measuring system shown in FIG. 1;

FIG. 7 is a block diagram of the measuring system to which a resistance measuring method of a second embodiment is applied;

FIG. 8 is a flow chart for illustrating the resistance measuring method of the second embodiment;

FIG. 9 is a block diagram of a measuring system to which a resistance measuring method of a third embodiment is applied;

FIG. 10 is a circuit diagram illustrating a principle of 6-wire resistance measurement of a measuring apparatus shown in FIG. 9;

FIG. 11 is a flow chart for illustrating the resistance measuring method of the third embodiment; and

FIG. 12 is a block diagram showing the configuration when the measuring system shown in FIG. 9 measures a different device under test from that in FIG. 9.

### DETAILED DESCRIPTION OF THE PREFERRED EMBODIMENTS

An embodiment of a resistance measuring method of the present disclosure will be described below with reference to the drawings.

An embodiment of a resistance measuring method uses a measuring apparatus 10 having a 4-wire resistance measuring function. The measuring apparatus 10 passes a current to a device under test (DUT) and also measures a voltage arising in a DUT 3 to calculate a resistance from the current and voltage.

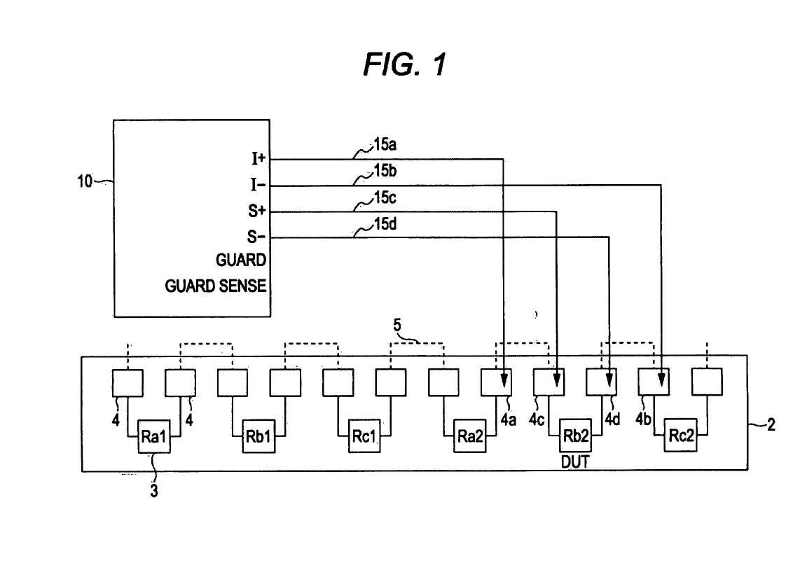

As shown in FIG. 1, a pair of pads 4 is electrically connected to the DUT 3. Here, FIG. 1 is a block diagram of a measuring system to which an embodiment of the resistance measuring method is applied. A plurality of sets are formed in a bar 2, with the DUT 3 and a pair of pads 4 together defined as a set.

The DUT 3 in the present embodiment is a head device applied to an HDD and is distinguished as Ra, Rb, and Rc in FIG. 1. Ra1 and Ra2 are manufacturing process verification devices and are the same type of device. Rb1 and Rb2 are reading devices and are the same type of devices. Rc1 and Rc2 are writing devices and are the same type of devices. Only a necessary part of the DUT 3 is eventually cut out from the bar 2 to become a product (head).

The pad 4 is a rectangular conductive part measuring 50 μm or 70 μm per side. The pad 4 has, for example, a laminated structure including copper and is manufactured by evaporating gold onto the top layer.

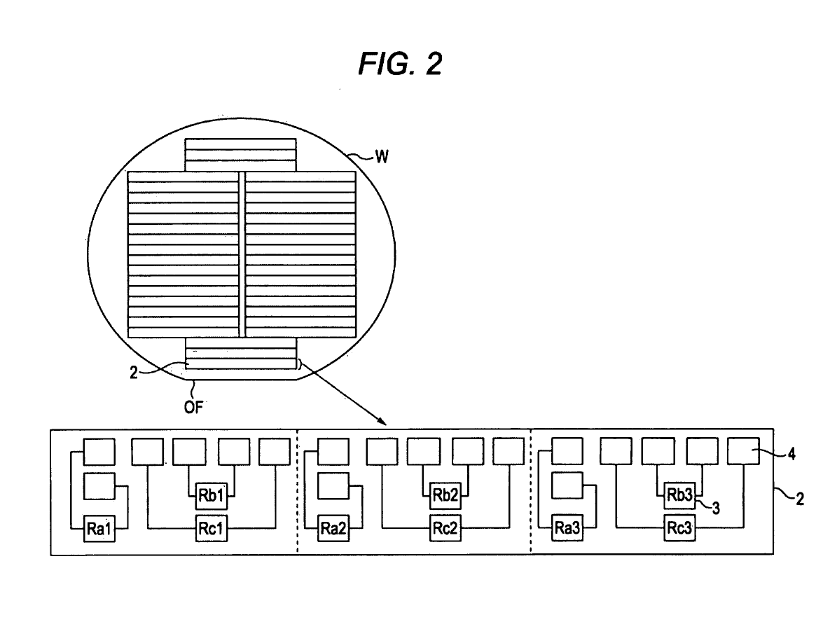

As show in FIG. 2, the bar 2 is cut out from a wafer W. Here, FIG. 2 is a schematic plane view of the wafer W and a schematic plane view of an example of the cutout bar 2. As shown in FIG. 2, the bar 2 is arranged in parallel to an orientation flat (OF) of the wafer W. As show in FIG. 2, the arrangement of the DUT 3 and pads 4 in each set inside the bar 2 is not limited to that shown in FIG. 1.

The measuring apparatus 10 may be a 4-wire resistance measuring apparatus having the 4-wire resistance measuring function or a 6-wire resistance measuring apparatus, and the 6-wire resistance measuring apparatus is used in the present embodiment. For example, a 2400 series source meter manufactured by Keithley Instruments can be used as such a 6-wire resistance measuring apparatus. In the present embodiment, only a pair of current terminals (I+ and I−) and a pair of voltage terminals (S+ and S−) of the measuring apparatus 10 are used and guard terminals (Guard and Guard Sense) are not used.

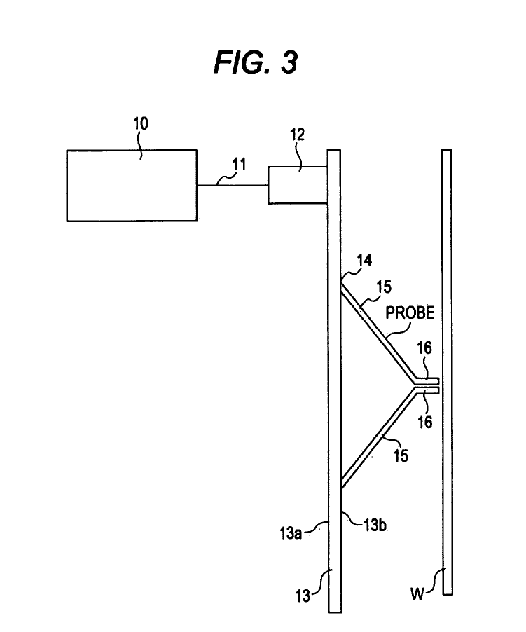

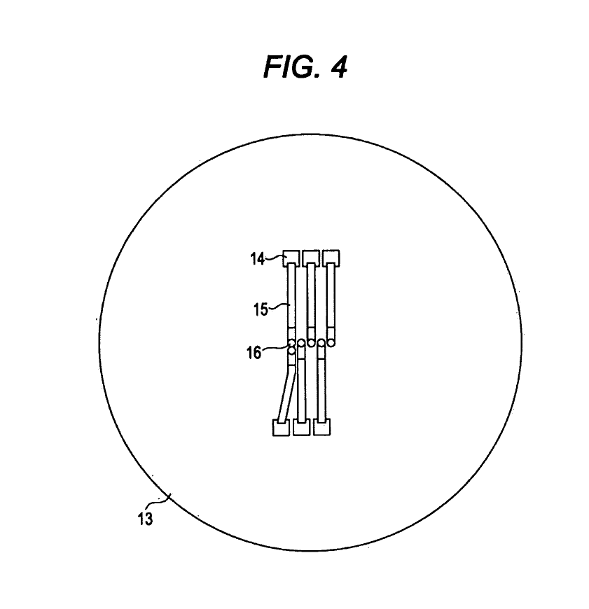

As shown in FIG. 3, the measuring apparatus 10 is connected to a front side 13a of a printed board 13 via a cable 11 and a connector 12. As shown in FIGS. 3 and 4, the printed board 13 is connected to probes 15 via lands 14 fixed to a backside 13b. The probe 15 is made of, for example, tungsten or a copper alloy. As shown in FIG. 3, the probe 15 has a tip part 16 in contact with the pad 4 (FIG. 2). Here, FIG. 3 is a schematic side view of the measuring system in the present embodiment and FIG. 4 is a rear view of the printed board 13 shown in FIG. 3.

In FIG. 1, the probe 15 includes a probe 15a connected to the current terminal I+ on the + side, a probe 15b connected to the current terminal I− on the − side, a probe 15c connected to the voltage sense terminal S+ on the + side, and a probe 15d connected to the voltage sense terminal S− on the − side. The pads 4 connected to the probes 15a to 15b are also distinguished as pads 4a to 4b, respectively. FIG. 1 shows a case in which the Rb2 is selected as the DUT 3.

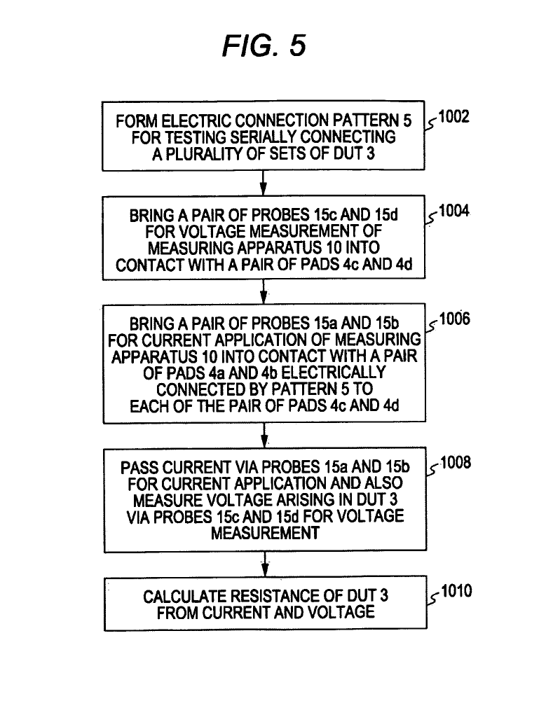

The resistance measuring method in the present embodiment will be described below with reference to FIG. 5.

First, an electric connection pattern 5 for testing that serially connects a plurality of sets of DUT 3 is formed (step 1002). In FIG. 1, the electric connection pattern 5 for testing is shown by dotted lines. The pattern 5 can be formed, like the pad 4, by evaporating gold, for example, in a process of forming a top layer of the pad 4. Naturally, the pattern 5 may also be formed in a process of forming an intermediate layer of the pad 4 in the same manner.

Next, a pair of the probes 15c and 15d for voltage measurement of the measuring apparatus 10 is brought into contact with a pair of the pads 4c and 4d of the DUT 3 (Rb2) (step 1004). Then, a pair of the probes 15a and 15b for current application of the measuring apparatus 10 is brought into contact with a pair of the pads 4a and 4b in contact with the probes 15c and 15d for voltage measurement and a pair of the pads 4c and 4d electrically connected by the pattern 5 (step 1006). Conventionally, the probes 15a and 15c come into contact with the pad 4c and the probes 15b and 15d come into contact with the pad 4d. Thus, the diameter of the probe 15 at the tip part 16 is forced to be reduced, making probe manufacture and measurement work more difficult and thus leading to reduced mechanical strength of the probe and higher running costs.

In contrast, in the present embodiment, only one probe 15 is caused to come into contact with one pad 4, as shown in FIG. 1, and therefore, the diameter of the probe 15 at the tip part 16 can be made larger than that of the conventional one. Consequently, the probe 15 can be manufactured more easily and also measuring work will be performed more easily because there is no need to arrange probes in such a way that two probes will not be brought into contact mutually. Further, the life of the probe 15 is extended because the diameter of the probe 15 is made larger, and a mechanical strength of the probe 15 can be increased. Since the life of the probe 15 is extended, replacement frequency of the probe 15 decreases, improving running costs of measurement. Further, when a case in which the same number of devices is measured are considered, costs are reduced because the number of probes is halved.

Next, a current is passed via the probes 15a and 15b for current application and also a voltage arising in the DUT 3 is measured via the probes 15c and 15d for voltage measurement (step 1008). The current flows from the terminal I+ to the terminal I− and its value is, for example, 10 mA. The measured voltage is, for example, 100 mV. Next, the resistance 10 Ω of the DUT 3 is calculated from the current and the measured voltage (step 1010).

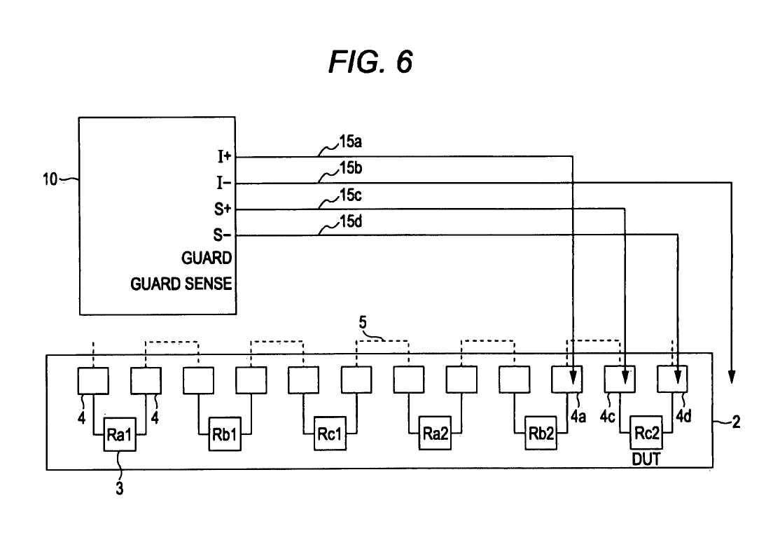

With the configuration of the pattern 5 shown in FIG. 1, as shown in FIG. 6, the pad corresponding to the pad 4b shown in FIG. 1 is gone for the DUT 3 (for example, the Rc2) at both ends and thus, the resistance measuring method in the embodiment discussed above may not be used. FIG. 6 is a plane view for illustrating a problem of the measuring system shown in FIG. 1.

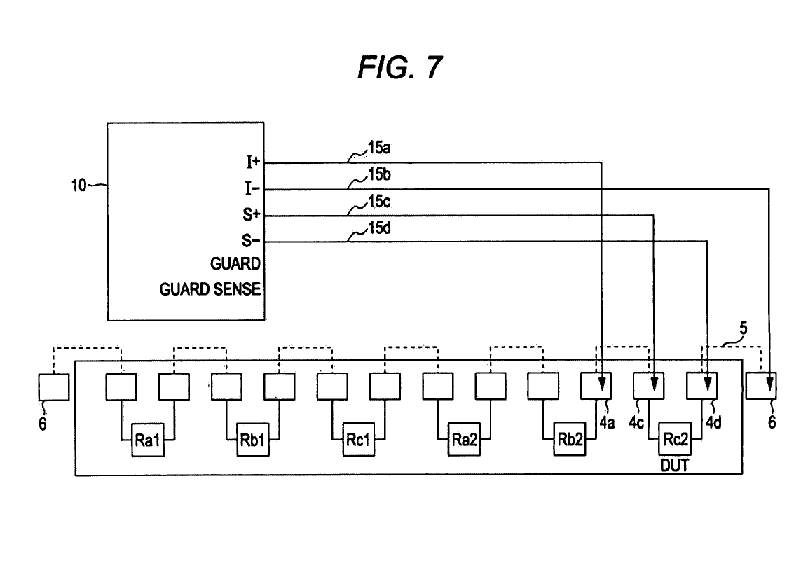

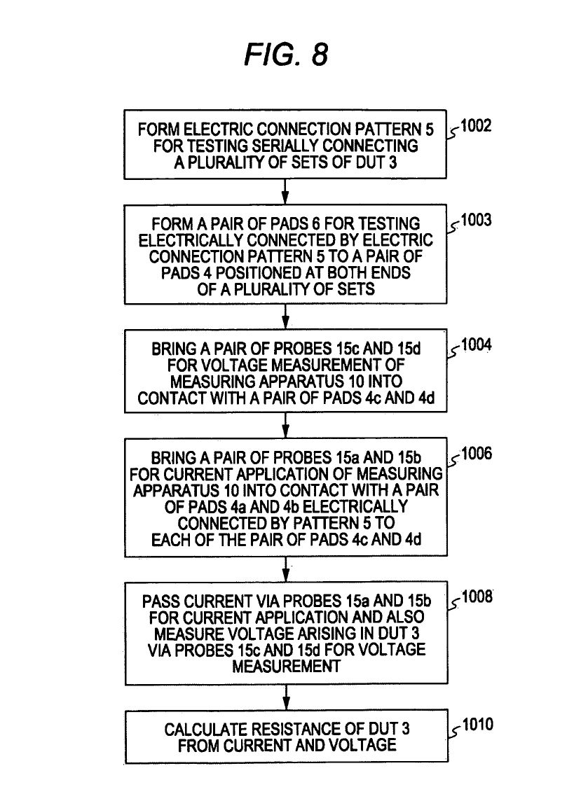

A resistance measuring method in a second embodiment will be described below, as shown in FIGS. 7 and 8. In FIG. 8, the same reference numerals are attached to the same steps as those in FIG. 6 and descriptions thereof are omitted. FIG. 7 is a schematic block diagram of the measuring system in the second embodiment. FIG. 8 is a flow chart for illustrating the resistance measuring method in the second embodiment.

As shown in FIG. 8, in the resistance measuring method in the second embodiment, a pair of pads 6 for testing in which each of the pads is connected to one of a pair of pads 4 positioned at both ends of a plurality of serially connected sets by the electric connection pattern 5, between steps 1002 and 1004 (step 1003). The pad 6 on the right side in FIG. 7 will have an effect similar to that of the pad 4b shown in FIG. 1. Forming the pad 6 on the outer side of the DUT 3 (Ra1 and Rc2 in FIG. 7) at both ends enables resistance measurement of the DUT 3 at both ends. The pad 6 is formed in a process similar to that of the pad 4 along with the pad 4 and, if resistance is not extremely high, may be formed from a material, such as titanium, different from that of the pad 4.

As shown in FIG. 7, only one probe 15 is caused to come into contact with one of the pads 4 or 6 in the present embodiment and thus, the diameter of the probe 15 at the tip part 16 can be made larger. Consequently, the probe 15 can be manufactured more easily, and also a high level of skills will not be needed for work because there is no need to arrange probes in such a way that two probes will not be brought into contact because they are too close to each other. Further, the life of the probe 15 is extended because mechanical strength of the probe 15 can be increased, as the diameter of the probe 15 is made larger. Moreover, since the life of the probe 15 is extended, replacement frequency of the probe 15 decreases, improving running costs of measurement. Further, when a case in which the same number of devices are measured is considered, costs are reduced because the number of probes is halved.

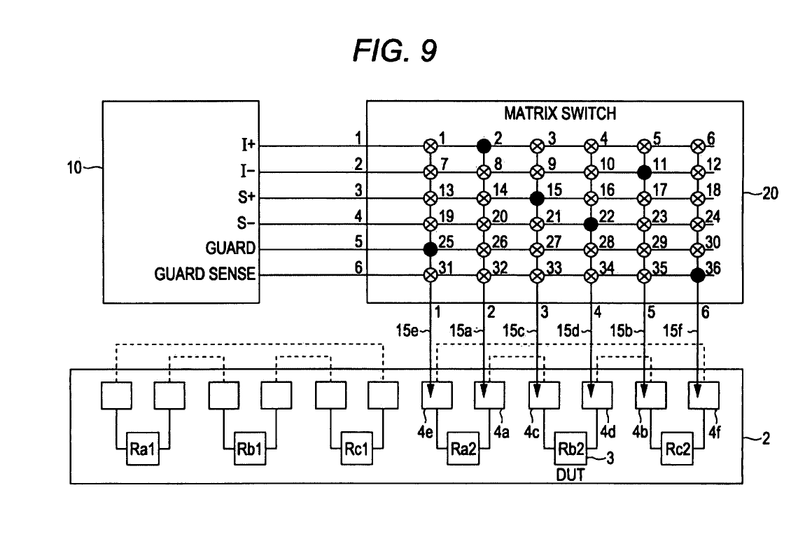

In contrast to the second embodiment, a third embodiment solves the problem shown in FIG. 6 with a configuration in which the pad 6 for testing is not formed. As shown in FIG. 9, the third embodiment uses the measuring apparatus 10 as a 6-wire resistance measuring apparatus and a matrix switch 20. Here, FIG. 9 is a schematic block diagram of the measuring system in the third embodiment.

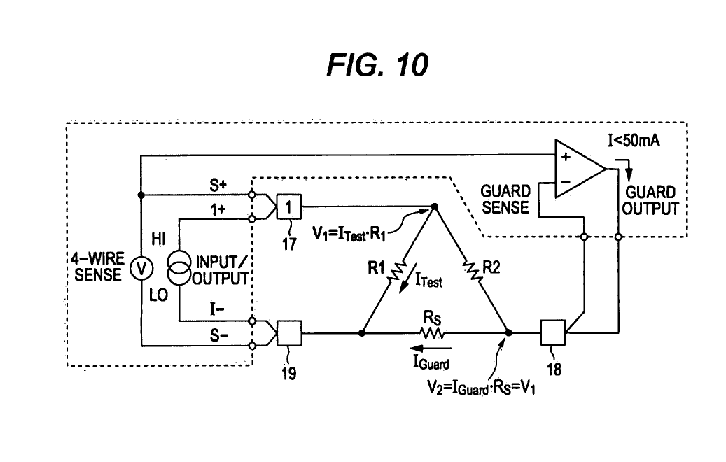

In contrast to FIGS. 1 and 7, the measuring apparatus 10 uses a pair of guard terminals (Guard and Guard Sense). The 6-wire resistance measuring apparatus is an apparatus for measuring a resistance R1 of an electric circuit connected between terminals 17 and 19 and including resistors R1, R2, and Rs connected circularly, as shown in FIG. 10. Four round marked terminals on the left side are a pair of current terminals and a pair of voltage sense terminals, and correspond to the terminal S+, terminal I+, terminal I−, and terminal S− from above respectively. A pair of guard terminals is connected to an intermediate terminal 18 between the resistors R2 and Rs that are connected in parallel across the resistor R1, and acts so that the terminals 17 and 18 are at the same potential. As a result, no current flows through R2 and a measuring current Itest flows only through R1. In FIG. 9, a probe connected to the Guard terminal is defined as 15e and that connected to the Guard Sense terminal is defined as 15f, and the pads 4 corresponding to them are distinguished as 4e and 4f, respectively.

The matrix switch 20 has six input terminals connected to one of six terminals of the measuring apparatus 10, and six output terminals to switch connection to the bar 2 of the measuring apparatus 10. In the matrix switch 20 shown in FIG. 9, black circle switches connect an input terminal and an output terminal and X marked switches do not connect an input terminal and an output terminal.

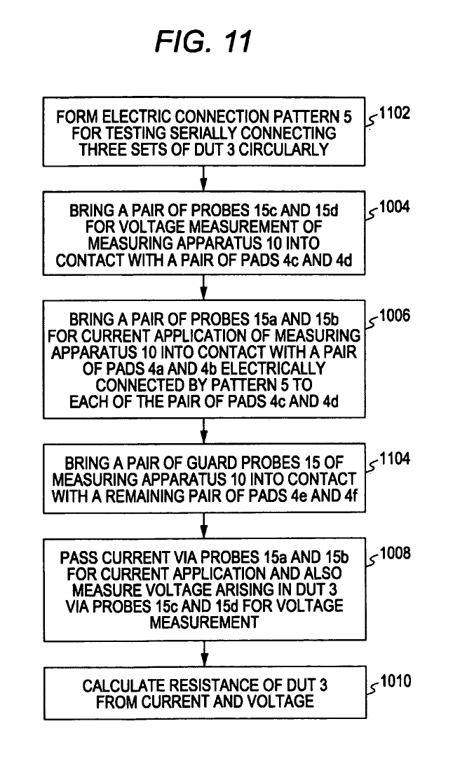

FIG. 9 shows a case in which the Rb2 is selected as the DUT 3. The resistance measuring method in the third embodiment will be described below with reference to FIG. 11.

First, the electric connection pattern 5 for testing that serially connects three sets or more of DUT 3 circularly is formed (step 1102). A difference from FIG. 1 is that the pattern 5 is formed circularly and the pads 4e and 4f are connected. Next, step 1004 and step 1006 are performed so that the probes 15a to 15d are brought into contact with the pads 4a to 4d. Next, a pair of the guard probes 15and 15f of the measuring apparatus 10 is caused to come into contact with a remaining pair of the pads 4e and 4f (step 1104). Then, step 1008 and step 1010 are performed. Since the terminals 17 and 18 are at the same potential, as already described with reference to FIG. 10, no current flows from the pad 4a to the Ra2 in FIG. 9 and all the measuring current flows to the Rb2 and no other current flows thereto.

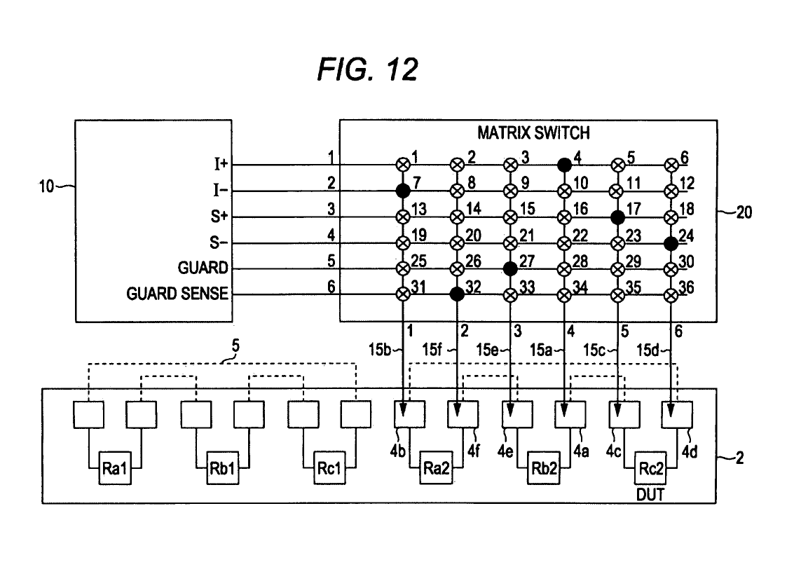

FIG. 12 shows a case in which the Rc2 at the right end is selected as the DUT 3 and the resistance of the DUT 3 can be measured by applying a method similar to that in FIG. 11.

As shown in FIG. 9, only one probe 15 is caused to come into contact one pad 4 also in the present embodiment and thus, the diameter of the probe 15 at the tip part 16 can be made larger. Consequently, the probe 15 can be manufactured more easily and also a high level of skills will not be needed for work because there is no need to arrange probes so as not to allow two probes to come into contact mutually. Further, the life of the probe 15 is extended because the diameter of the probe 15 is made relatively larger, and a mechanical strength of the probe 15 can be increased. Since the life of the probe 15 is extended, replacement frequency of the probe 15 decreases, improving running costs of measurement. Further, when a case in which the same number of devices are measured is considered, costs are reduced because the number of probes is halved.

Embodiments of the present invention have been described above, but the present invention is not limited to these embodiments, and various modifications and alterations can be made without departing from the scope thereof.

What is claimed is:

1. A resistance measuring method by which a current is passed to a plurality of sets of devices under test, each of the set has a device under test and a pair of pads electrically connected to the device under test, by use of a measuring apparatus having a 4-wire resistance measuring function and a voltage arising in the device under test is measured to calculate a resistance of the device under test from the current and voltage, the method comprising:
forming an electric connection pattern for testing that serially connects the plurality of sets of the devices under test;
causing a pair of probes for voltage measurement of the measuring apparatus to come into contact with the pair of pads of the device under test; and
causing a pair of probes for current application of the measuring apparatus to come into contact with a pair of pads electrically connected by the electric connection pattern to each of the pair of pads of the device under test.

2. The resistance measuring method according to claim 1, further comprising:
forming a pair of pads for testing electrically connected by the electric connection pattern for testing to each of pads positioned at both ends of the plurality of serially connected sets.

3. A resistance measuring method by which a current is passed to three sets or more of devices under test, each of which has a device under test and a pair of pads electrically connected to the device under test, by use of a measuring apparatus having a 6-wire resistance measuring function and a voltage arising in the device under test is measured to calculate a resistance of the device under test from the current and voltage, the method comprising:
circularly forming an electric connection pattern for testing that serially connects three sets or more of the devices under test;
causing a pair of probes for voltage measurement of the measuring apparatus to come into contact with a pair of pads of the three sets or more of the devices under test;
causing a pair of probes for current application of the measuring apparatus to come into contact with a pair of pads electrically connected by the electric connection pattern to each of the pair of pads; and
causing a pair of guard probes of the measuring apparatus to come into contact with a pair of pads among one pair or more of remaining pads mutually connected by the electric connection pattern for testing.
